(19) United States
(12) Patent Application Publication
(10) Pub. No.: US 2024/0145454 A1
(43) Pub. Date: May 2, 2024

(54) OPTICAL SENSOR WITH TSV STRUCTURE

(71) Applicant: TEXAS INSTRUMENTS INCORPORATED, DALLAS, TX (US)

(72) Inventor: DAIKI KOMATSU, Hiji (JP)

(21) Appl. No.: 17/977,810

(22) Filed: Oct. 31, 2022

(51) Int. Cl. H01L 25/16; H01L 23/00; H01L 25/075; H01L 31/173

(52) U.S. Cl. CPC H01L 25/167; H01L 24/24; H01L 25/0753; H01L 31/173; H01L 2924/1204

(57) ABSTRACT

An electronic device includes a substrate and a die having an active surface where the die is disposed on the substrate. A sensor is disposed on the active surface of the die such that the sensor is exposed to an external environment. Electrical interconnects are disposed on the active surface of the die near a perimeter of the die. Conductive terminals have a first end attached to a contact surface of the electrical interconnects and a second end that attaches to an external terminal.

### TECHNICAL FIELD

The present disclosure relates to an electronic device and more specifically, to an integrated circuit package that includes a sensor area exposed to a surrounding environment.

### BACKGROUND

Integrated circuit (IC) sensor packages are used as sensor packages to measure or detect various physical properties of an environment such as optics, humidity, temperature, sound, pressure, adverse environmental conditions, etc. Thus, IC sensor packages include a sensor to sense the physical property and other circuitry to process the sensed physical property. As a result, the sensor must be exposed to the environment while the other circuitry must be protected from the environment so as not to damage the circuitry. In addition, an efficient and cost effective method to fabricate external conductive terminals that provide a connection from the sensor to an external device or board (e.g., printed circuit board) must be provided.

### SUMMARY

In described examples, an electronic device includes a substrate and a die having an active surface where the die is disposed on the substrate. A sensor is disposed on the active surface of the die such that the sensor is exposed to an external environment. Electrical interconnects are disposed on the active surface of the die near a perimeter of the die. Conductive terminals have a first end attached to a contact surface of the electrical interconnects and a second end configured to attach to an external terminal.

In another described example, a method includes attaching dies on a substrate via a die attach material and placing a sensor in a sensor area on an active surface of the dies. Electrical interconnects are deposited on the active surface of the dies near a perimeter of the dies. Channels are formed between adjacent dies. A first photoresist material layer is deposited over the substrate, the dies, the sensor, and the electrical interconnects. The first photoresist material layer is patterned to form channel openings in the channels, to form sensor openings over each sensor, and to expose a portion of a contact surface of the electrical interconnects. A metal plating layer is deposited in the channel openings and is electrically coupled to the contact surface of the electrical interconnects and abuts the first photoresist material layer surrounding the sensor. The substrate is singulated between adjacent dies to expose end portions of the metal plating layer.

In still another described example, a method of fabricating an integrated circuit sensor package includes placing a sensor and electrical interconnects on a die attached to a substrate. A cavity is formed in a permanent photoresist material layer that surrounds the sensor. Conductive terminals are coupled to the electrical interconnects, the conductive terminals extending along a side of the electrical interconnects, the die, and the substrate to an external terminal.

### BRIEF DESCRIPTION OF THE DRAWINGS

FIG. 1 illustrates a top view of an example electronic device.

FIG. 2 illustrates a cross section view of the example electronic device of FIG. 1.

FIG. 3 illustrates a cross section view of a substrate in the early stages of fabrication of an array of electronic devices of FIGS. 1 and 2.

FIG. 4 illustrates a cross section view of the array in FIG. 3 including a die attach material.

FIG. 5 illustrates a cross section view of the array of FIG. 4 including dies attached to the die attach material.

FIG. 6 illustrates a cross section view of the array of FIG. 5 including sensors and electrical interconnects attached to the die.

FIG. 7 illustrates a cross section view of the array of FIG. 6 after undergoing a blade sawing process to form channels in the substrate.

FIG. 8 illustrates a cross section view of the array of FIG. 7 after undergoing an application of a first photoresist material layer.

FIG. 9 illustrates a cross section view of the array of FIG. 8 after undergoing a process to pattern and develop the first photoresist material layer.

FIG. 10 illustrates a cross section view of the array of FIG. 9 after undergoing an application of a second photoresist material layer.

FIG. 11 illustrates a cross section view of the array of FIG. 10 after undergoing deposition of a seed layer.

FIG. 12 illustrates a cross section view of the array of FIG. 11 after undergoing deposition of a metal plating layer.

FIG. 13 illustrates a cross section view of the array of FIG. 12 after undergoing removal of the second photoresist material layer.

FIG. 14 illustrates a top view of the array of FIG. 13 illustrating locations of exposed portions of the seed layer.

FIG. 15 illustrates a top view of the array of FIG. 14 after undergoing an etching process to remove the exposed portions of the seed layer.

FIG. 16 illustrates a cross section view of the array of FIG. 15.

FIG. 17 illustrates a cross section view of the array of FIG. 16 after undergoing a back grinding process.

FIG. 18 illustrates a cross section view of the array of FIG. 17 undergoing a blade sawing process to singulate the electronic devices from an array.

FIG. 19 illustrates a cross section view of electronic devices of FIG. 18 after undergoing the singulation process.

### DETAILED DESCRIPTION

Integrated circuit (IC) sensor packages are used as sensor packages to measure or detect various physical properties of an environment such as optics, humidity, temperature, sound, pressure, adverse environmental conditions, etc. Thus, IC sensor packages include a sensor to sense the physical property and other circuitry to process the sensed physical property. As a result, the sensor must be exposed to the environment while the other circuitry must be protected from the environment so as not to damage the circuitry. In addition, an efficient and cost effective method to fabricate external conductive terminals that provide a connection from the sensor to an external device or board (e.g., printed circuit board) must be provided.

Current fabrication processes to fabricate an IC sensor package (e.g., optical sensor) are complex and slow. Optical sensors include through silicon vias that are drilled through the package to provide a connection from the sensor to the external board. This process does not lend itself to easily and cost effectively alter the fabrication process for different designs and/or package sizes. Investment in different types of equipment introduces significant increases in design costs, manufacturing costs, development time, and manufacturing time.

Disclosed herein is an electronic device and more specifically, an integrated circuit (IC) sensor package and method of fabricating the IC sensor package that overcomes the challenges described above. The method of fabricating the IC sensor package includes forming through silicon vias (TSV) in an array of IC sensor packages and sawing through the TSV's via a blade sawing process to singulate the IC sensor packages as opposed to a drilling process. The resulting IC sensor packages include a sensor attached to a die where the sensor is exposed to an external environment. The sensor may be used to measure various physical properties of an environment such as optics, humidity, temperature, sound, pressure, adverse environmental conditions, etc. The IC packages further include external conductive terminals that are formed during fabrication of the TSV's. The external conductive terminals provide a connection between the sensor, via the die and interconnects, and an external board (e.g., printed circuit board), via solder.

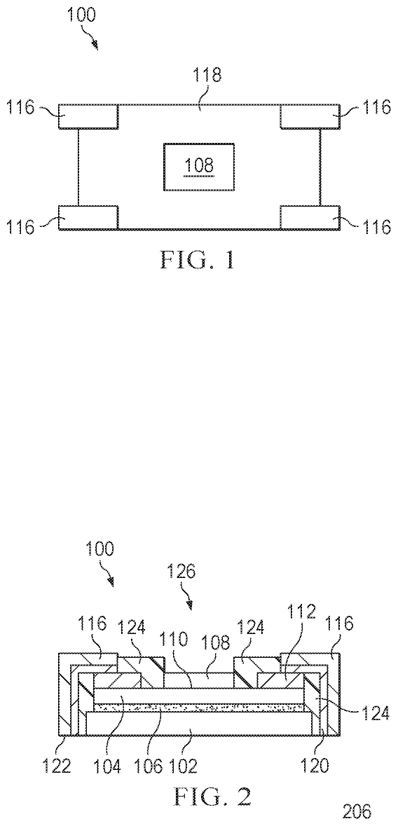

FIGS. 1 and 2 are top and cross section views respectively of an electronic device (e.g., IC sensor package) 100 comprised of a substrate 102, a die 104 disposed on the substrate 102 via a die attach material 106. The electronic device 100 further includes a sensor 108 attached to a sensor area on an active surface 110 of the die 104. The active surface 110 of the die 104 may include other circuitry coupled to the sensor 108 that is configured to receive and process signals from the sensor 108 in an appropriate manner. The sensor 108 may be configured to sense any of a variety of physical properties, such as light, humidity, sound, pressure, bulk acoustic waves, stress, temperature, current, voltage, power, motion, acceleration, magnetic fields, and other physical properties.

Electrical interconnects (e.g., conductive pads, contacts) 112 are disposed at various locations on the active surface 110 of the die 104. A first end 114 of conductive terminals 116 are electrically coupled to a contact surface 118 of the electrical interconnects 112 via an optional seed layer 120. It is to be understood that the seed layer 120 is an optional layer and is not required. A second end 122 of the conductive terminals 116 are connected to an external terminal on an external device (e.g., printed circuit board) via external interconnects (e.g., solder). A permanent photo resist material 124 is disposed on portions of the die 104 and portions of the electrical interconnects 112 such that the die 104 and electrical interconnects 112 are protected from the external environment. The permanent photoresist material 124, however, surrounds the sensor 108 and thus does not cover the sensor 108. As a result, the permanent photoresist material layer 124 forms a cavity 126 where the sensor 108 resides. Therefore, the sensor 108 is exposed to the external environment to sense the required physical property. In addition, the permanent photoresist material layer 124 extends along a side of the electrical interconnects 112, the die 104, and the substrate 102 and is substantially flush with a mounting surface 128 of the substrate 102. The seed layer 120 and conductive terminals 116 overlie the permanent photoresist material layer 124 extending along the side.

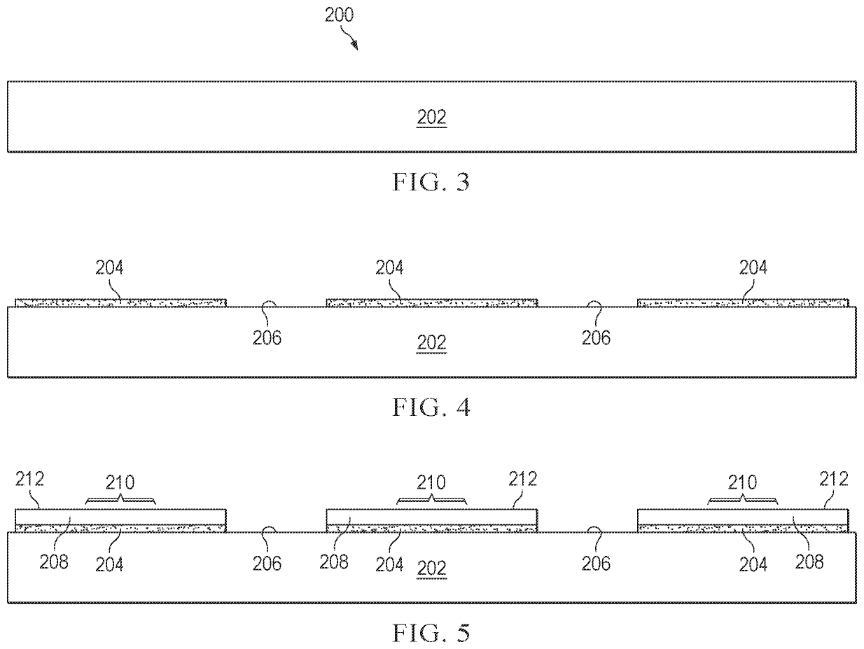

FIGS. 3-19 illustrate a fabrication process associated with the formation of the electronic device (e.g., IC sensor package) 100 illustrated in FIGS. 1 and 2. Though depicted sequentially as a matter of convenience, at least some of the actions shown can be performed in a different order and/or performed in parallel. Alternatively, some implementations may perform only some of the actions shown. Still further, although the example illustrated in FIGS. 3-19 is an example method illustrating the example configuration of FIGS. 1 and 2, other methods and configurations are possible. It is understood that although the method illustrated in FIGS. 3-19 depicts the fabrication process of a three IC sensor packages, the process applies to an array of IC sensor packages. Thus, after fabrication of the array of IC sensor packages the array is singulated to separate each IC sensor package from the array.

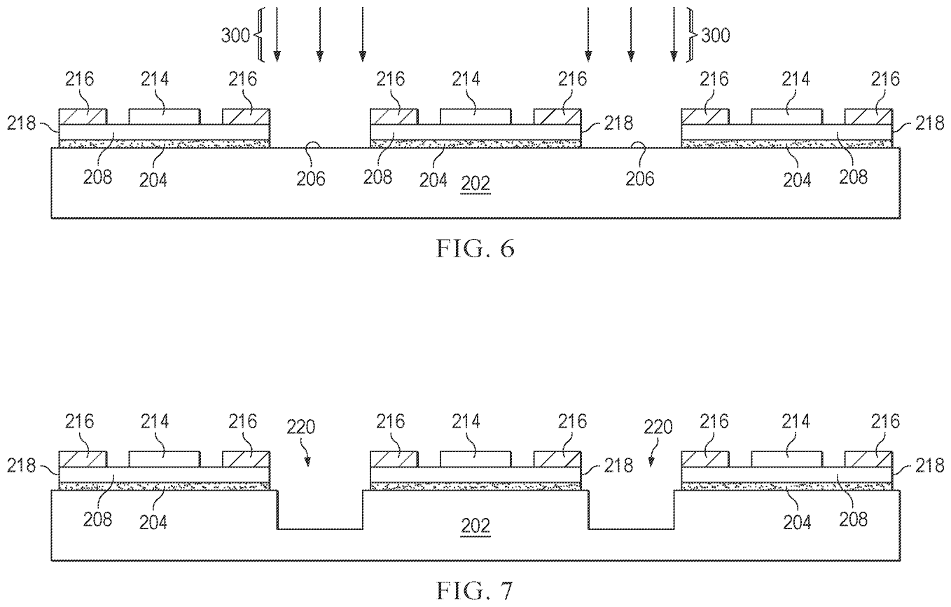

Referring to FIG. 3, the fabrication process 200 begins with a substrate (e.g., wafer) 202. Die attach material 204 is deposited in locations on a surface 206 of the substrate 202 resulting in the configuration in FIG. 4. Dies 208 are attached to the die attach material 204 resulting in the configuration in FIG. 5. Each die 208 includes a sensor area 210 on an active surface 212 of each die 208. A sensor 214 is attached in the sensor area 210 of each die 208. In addition, electrical interconnects (e.g., contacts, pads) 216 are attached to the active surface 212 near a perimeter 218 of the dies 208 resulting in the configuration in FIG. 6.

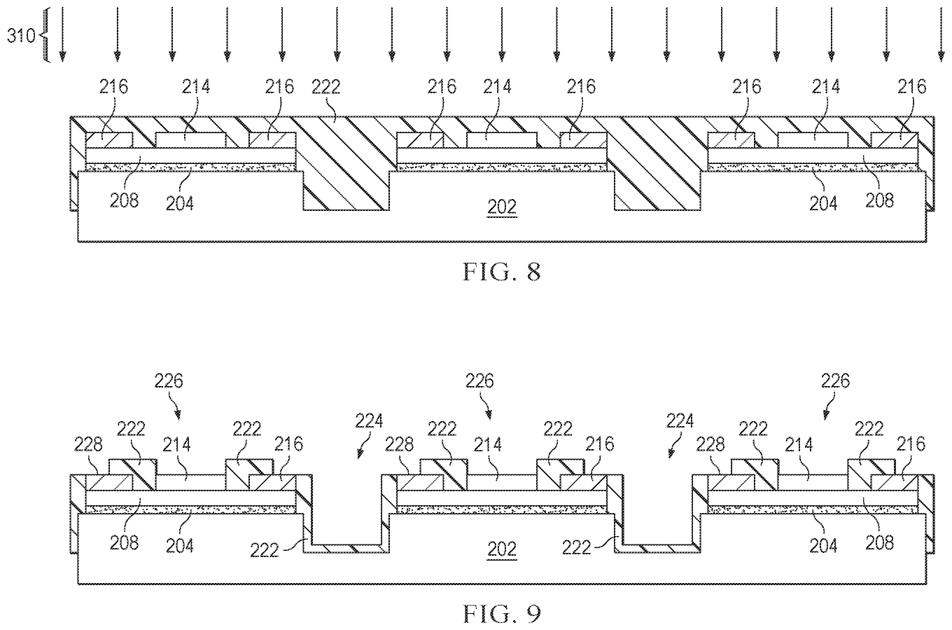

The configuration in FIG. 6 undergoes a partial cutting process 300 via a blade saw to form channels or recesses 220 in the substrate 202 between adjacent dies 208 resulting in the configuration in FIG. 7. A first (permanent) photoresist material layer 222 is deposited over the substrate 202, the dies 208, the sensors 214, and the electrical interconnects 216 resulting in the configuration in FIG. 8. The first photoresist material layer 222 in FIG. 8 undergoes a patterning process 310 to pattern channel openings 224 in the channels 220 and sensor openings or cavities 226 over the sensors 214 thereby exposing the sensors 214 to the external environment resulting in the configuration in FIG. 9. As illustrated in FIG. 9, a layer of the first photoresist material layer 222 remains in the channel openings 224 and in areas surrounding the sensor 214. The first photoresist material layer 222 in the areas surrounding the sensors 214 form the cavities 226 over the sensor area 210 on the active surface 212 of each die 208 where the sensors 214 reside. The remaining portion of the first photoresist material layer 222 is thus permanent and is not removed. In addition, portions of the first photoresist material layer 222 are patterned to expose a portion of a contact surface 228 on each electrical interconnect 216 as illustrated in FIG. 9.

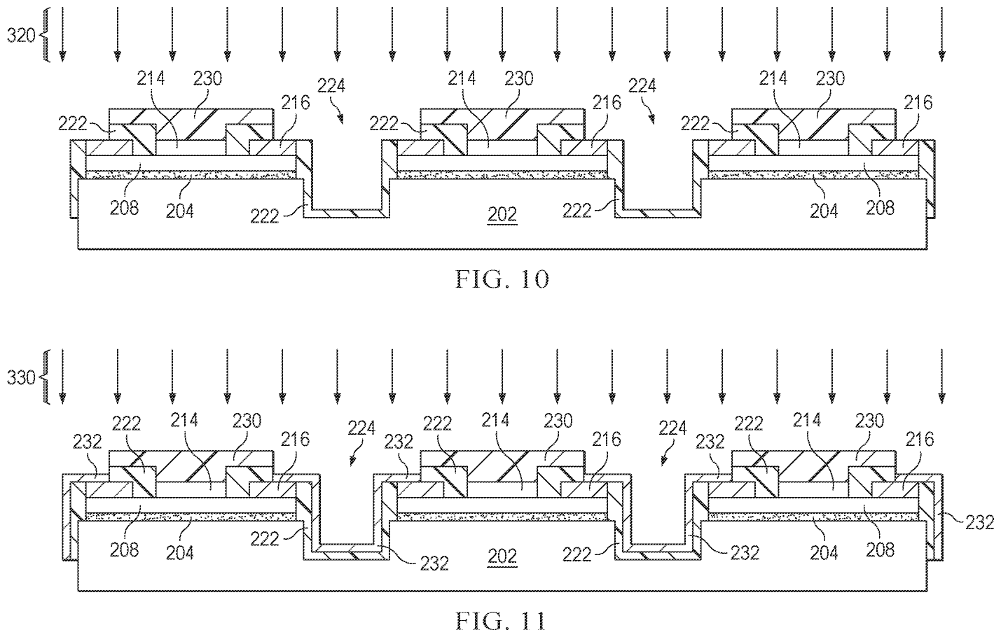

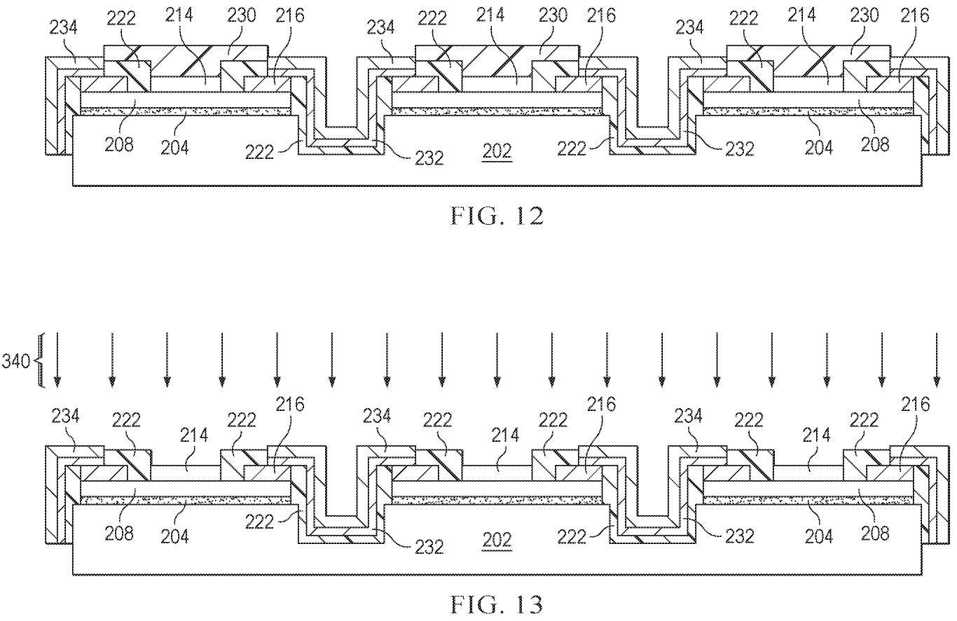

A second (non-permanent) photoresist material layer 230 is deposited and patterned to overlie the sensors 214 and the first photoresist material layer 222 surrounding the sensor 214 resulting in the configuration in FIG. 10. The configuration in FIG. 10 undergoes a first deposition process 320 to deposit a seed layer 232 in the channel openings 224 over the first photoresist material layer 222. The seed layer 232 extends over the exposed contact surface 228 of the electrical interconnects 216 and abuts the first photoresist material layer 222 that surrounds the sensor 214 resulting in the configuration in FIG. 11. The configuration in FIG. 11 undergoes a second deposition process 330 (e.g., electroplating) to deposit a metal plating layer 234 (e.g., copper) over the seed layer 232 resulting in the configuration in FIG. 12.

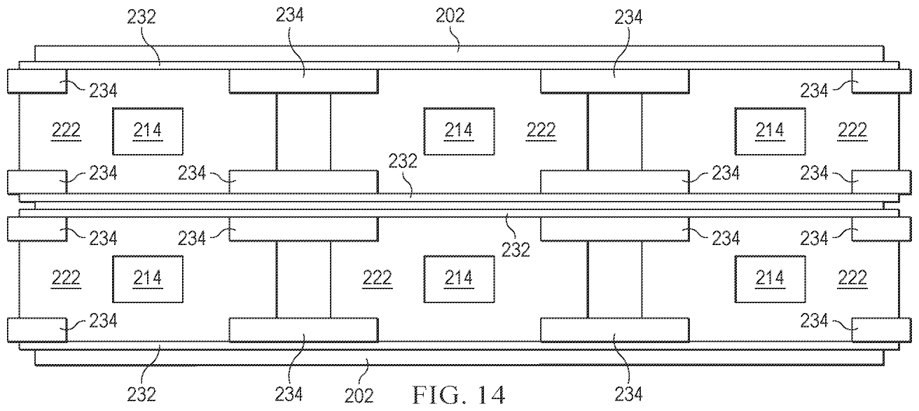

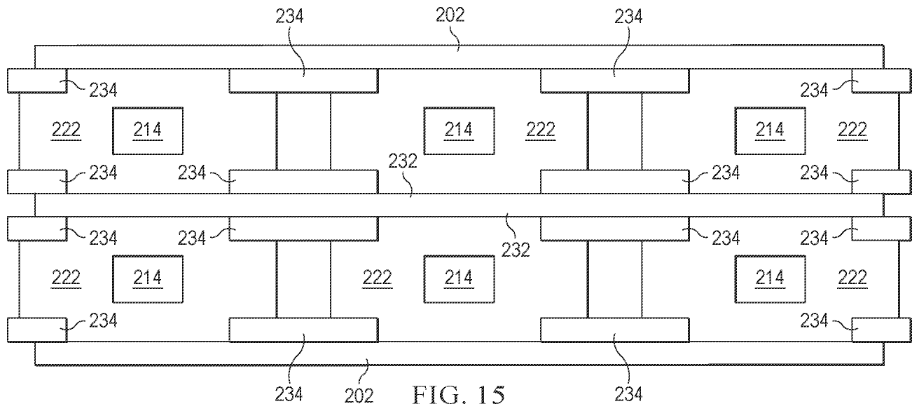

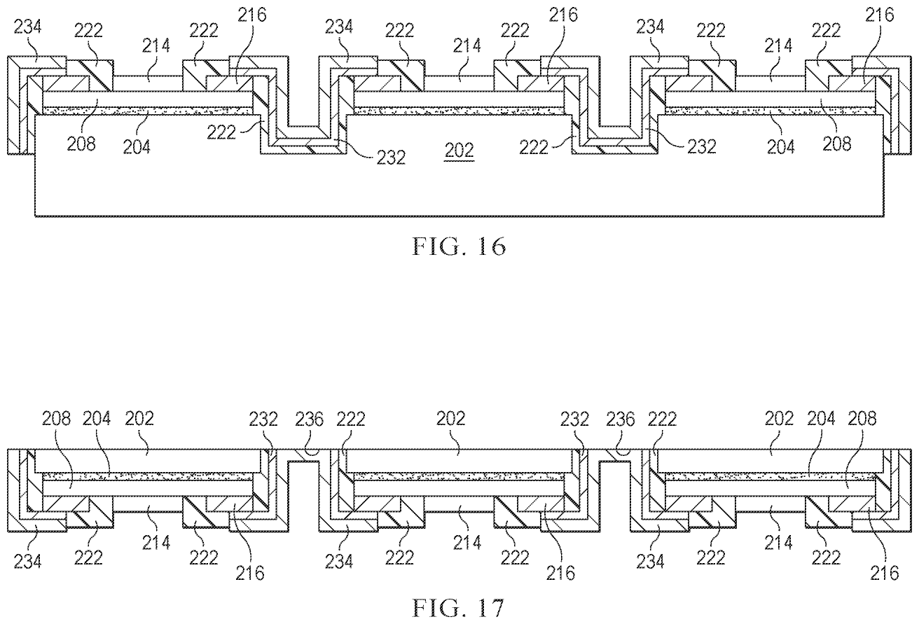

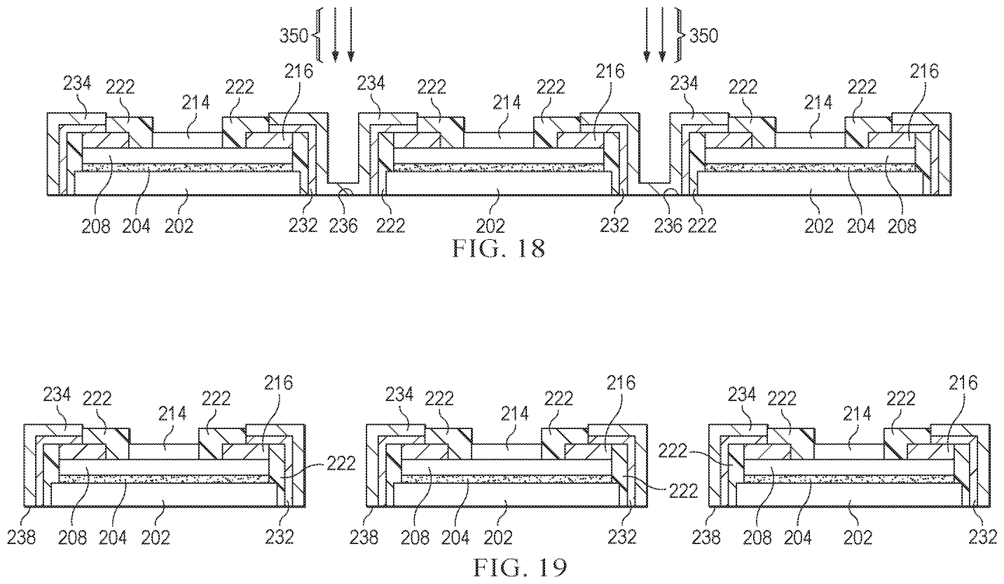

The second photoresist material layer 230 is stripped resulting in the configuration in FIG. 13. The configuration in FIG. 13 undergoes an etching process 340 to remove exposed portions of the seed layer 232. Since the exposed portions of the seed layer 232 are not viewable in the side view of FIG. 13, a top view of FIG. 13 is illustrated in FIG. 14 that illustrates the locations of the exposed portions of the seed layer 232. FIG. 15 is a top view of FIG. 13 after the exposed portions of the seed layer 232 are removed via the etching process 340. The resulting side view is illustrated in FIG. 16. The configuration in FIG. 16 is rotated 180° (i.e., flipped upside down) and the substrate 202 is back grinded thereby exposing a surface 236 of the metal plating layer 234 resulting in the configuration in FIG. 17. The configuration in FIG. 17 is once again rotated 180° (i.e., flipped right side up) and singulated between adjacent dies 208 via a blade sawing process 350 illustrated in FIG. 18 thereby exposing end portions 238 of the metal plating layer 234 and forming individual IC sensor packages 250 illustrated in FIG. 19.

Deposition of the metal plating layer 234 forms the TSV's in an array of IC sensor packages. The blade sawing process 350 illustrated in FIG. 18 saws through the TSV's between adjacent dies 208 in the array to singulate the IC packages. Thus, the deposition of the metal plating layer 234 and the blade sawing process 350 form the conductive terminals 116 illustrated in FIG. 1.

Described above are examples of the subject disclosure. It is, of course, not possible to describe every conceivable combination of components or methodologies for purposes of describing the subject disclosure, but one of ordinary skill in the art may recognize that many further combinations and permutations of the subject disclosure are possible. Accordingly, the subject disclosure is intended to embrace all such alterations, modifications and variations that fall within the spirit and scope of the appended claims. In addition, where the disclosure or claims recite “a,” “an,” “a first,” or “another” element, or the equivalent thereof, it should be interpreted to include one or more than one such element, neither requiring nor excluding two or more such elements. Furthermore, to the extent that the term “includes” is used in either the detailed description or the claims, such term is intended to be inclusive in a manner similar to the term “comprising” as “comprising” is interpreted when employed as a transitional word in a claim. Finally, the term “based on” is interpreted to mean based at least in part.

What is claimed is:

1. An electronic device comprising:
a substrate;
a die having an active surface, the die being disposed on the substrate;
a sensor disposed on the active surface of the die, the sensor exposed to an external environment;
electrical interconnects disposed on the active surface of the die near a perimeter of the die; and
conductive terminals having a first end attached to a contact surface of the electrical interconnects and a second end configured to attach to an external terminal.

2. The electronic device of claim 1 further comprising a permanent photoresist material layer surrounding the sensor.

3. The electronic device of claim 2, wherein the permanent photoresist material layer forms a cavity where the sensor resides on the active surface of the die.

4. The electronic device of claim 3, wherein the conductive terminals extend along a side of the electrical interconnects, the die, and the substrate and is spaced from the electrical interconnects, the die, and the substrate by the permanent photoresist material layer.

5. The electronic device of claim 1 further comprising a seed layer disposed between the electrical interconnects and the contact surface of the electrical interconnects.

6. The electronic device of claim 1, wherein the die is attached to the substrate via a die attach material.

7. A method comprising:
attaching dies on a substrate via a die attach material;
placing a sensor in a sensor area on an active surface of the dies;
depositing electrical interconnects on the active surface of the dies near a perimeter of the dies;
forming channels between adjacent dies;
depositing a first photoresist material layer over the substrate, the dies, the sensor, and the electrical interconnects;
patterning the first photoresist material layer to form channel openings in the channels, to form sensor openings over each sensor, and to expose a portion of a contact surface of the electrical interconnects;
depositing a metal plating layer in the channel openings, the metal plating layer electrically coupled to the contact surface of the electrical interconnects and abutting the first photoresist material layer surrounding the sensor; and
singulating the substrate between adjacent dies to expose end portions of the metal plating layer.

8. The method of claim 7, wherein forming channels between adjacent dies includes partially cutting into the substrate with a cutting blade.

9. The method of claim 7, wherein depositing a metal plating layer in the channel openings forms through silicon vias in the substrate between adjacent dies.

10. The method of claim 7, wherein prior to depositing a metal plating layer in the channel openings, the method further comprising depositing a second photoresist material layer over each sensor and the first photoresist material layer surrounding the sensor.

11. The method of claim 10 further comprising depositing a seed layer in the channel openings, the seed layer electrically coupled to the contact surface of the electrical interconnects and abutting the first photoresist material layer surrounding the sensor.

12. The method of claim 11, wherein prior to singulating the substrate between adjacent dies to expose end portions of the metal plating layer, the method further comprising removing the second photoresist material layer.

13. The method of claim 12 further comprising etching exposed portions of the seed layer.

14. The method of claim 13 further comprising back grinding the substrate to expose a surface of the metal plating layer.

15. A method of fabricating an integrated circuit sensor package comprising:
placing a sensor and electrical interconnects on a die attached to a substrate;
forming a cavity in a permanent photoresist material layer surrounding the sensor; and
coupling conductive terminals to the electrical interconnects, the conductive terminals extending along a side of the electrical interconnects, the die, and the substrate to an external terminal.

16. The method of claim 15, wherein placing a sensor and electrical interconnects on a die attached to a substrate includes attaching the sensor to a sensor area on an active surface of the die and attaching the electrical interconnects on the active surface of the die near a perimeter of the die.

17. The method of claim 16, wherein forming a cavity in a permanent photoresist material layer surrounding the sensor includes patterning the permanent photoresist material layer to form the cavity over the sensor area on the active surface of the die and to expose the sensor to an external environment.

18. The method of claim 17, wherein prior to coupling conductive terminals to the electrical interconnects, the method further comprising depositing a seed layer on a contact surface of the electrical interconnects, the seed layer extending along a side of the electrical interconnects, the die, and the substrate to the external terminal.

19. The method of claim 18, wherein coupling conductive terminals to the electrical interconnects includes depositing a metal plating layer on the seed layer.

20. The method of claim 19, wherein the seed layer and the metal plating layer both abut the permanent photoresist material layer surrounding the sensor.
